(19) United States
(12) Patent Application Publication
(10) Pub. No.: US 2009/0256639 A1
(43) Pub. Date: Oct. 15, 2009

(54) ALL-DIGITAL PHASE-LOCKED LOOP AND BANDWIDTH ADJUSTING METHOD THEREFORE

(75) Inventors: Huan-Ke Chiu, Jhudong Township (TW); Chun-Jen Chen, Sanchong City (TW)

Correspondence Address: LOWE HAUPTMAN HAM & BERNER, LLP, 1700 DIAGONAL ROAD, SUITE 300, ALEXANDRIA, VA, 22314, US

(73) Assignee: INDUSTRIAL TECHNOLOGY RESEARCH INSTITUTE, Hsinchu (TW)

(21) Appl. No.: 12/401,501

(22) Filed: Mar. 10, 2009

(30) Foreign Application Priority Data
Apr. 14, 2008 (TW) 97113456

(51) Int. Cl. H03L 7/00

(52) U.S. Cl. 331/16

(57) ABSTRACT

An all-digital phase-locked loop is disclosed. The all-digital phase-locked loop includes a digitally controlled oscillator, a phase detector, a loop filter, and a bandwidth modification unit. The digitally controlled oscillator is controlled by an oscillator tuning word to generate a variable signal, wherein the oscillator tuning word includes a first tuning word and a second tuning word respectively to adjust the capacitance of a first capacitor set and the capacitance of a second capacitor set. The phase detector measures a phase error between the variable signal and a reference signal. The loop filter receives the phase error to generate an initial tuning word. The bandwidth modification unit receives the initial tuning word to adjust the initial tuning word to generate the tuning word according to the available usage range of the first capacitor set and the second capacitor set.

### CROSS REFERENCE TO RELATED APPLICATIONS

This application claims priority of Taiwan Patent Application No. 097113456, filed on Apr. 14, 2008, the entirety of which is incorporated by reference herein.

### BACKGROUND OF THE INVENTION

1. Field of the Invention

The invention relates to an all-digital phase-locked loop, and more particularly to an all-digital phase-locked loop which can adjust its bandwidth.

2. Description of the Related Art

RF transmitter with polar architecture becomes the major technology of present wireless communication because it is easily to maintain the effective of the power amplifier. However, when the polar architecture transforms the I/Q signals with limit bandwidth to polar signals which comprise magnitude signal and phase signal, it requires quite large bandwidth to maintain the quality of signals. When the bandwidth for the magnitude signal and phase signal is limited, error vector magnitude (EVM) and spectral re-growth increase. Therefore, how to find a simple and easy way to adjust the bandwidth and increase the bandwidth usage range is desirable problem.

### BRIEF SUMMARY OF THE INVENTION

An embodiment of a method for adjusting the bandwidth of an all-digital phase-locked loop is provided. The all-digital phase-locked loop comprises a digitally controlled oscillator controlled by an oscillator tuning word to generate a variable signal, the oscillator tuning word comprises a first tuning word and a second tuning word respectively to adjust the capacitance of a first capacitor set and the capacitance of a second capacitor set, and the frequency range of the digitally controlled oscillator capable to be adjusted by the first tuning word is broader than that capable to be adjusted by the second tuning word. The method comprises: enabling both the first capacitor set and the second capacitor set; executing a frequency-phase-locked processing by the all-digital phase-locked loop; setting the capacitance variation range of the second capacitor set to be between a first upper value and a first bottom value; determining whether the second tuning word is between the first upper value and the first bottom value; when the second tuning word is not between the first upper value and the first bottom value, adjusting the first tuning word and the all-digital phase-locked loop re-executing the frequency-phase-locked procedure.

An embodiment of an all-digital phase-locked loop is disclosed. The all-digital phase-locked loop comprises a digitally controlled oscillator, a phase detector, a loop filter and a bandwidth modification unit. The digitally controlled oscillator is controlled by an oscillator tuning word to generate a variable signal, wherein the oscillator tuning word comprises a first tuning word and a second tuning word respectively to adjust the capacitance of a first capacitor set and the capacitance of a second capacitor set, and the frequency range of the digitally controlled oscillator capable to be adjusted by the first tuning word is broader than that capable to be adjusted by the second tuning word. The phase detector measures a phase error between the variable signal and a reference signal. The loop filter receives the phase error to generate an initial tuning word. The bandwidth modification unit receives the initial tuning word to adjust the initial tuning word to generate the tuning word according to the available usage range of the first capacitor set and the second capacitor set.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a schematic diagram of an embodiment of an all-digital phase-locked loop according to the invention.

FIG. 2 is a schematic diagram of phase modulation when the bandwidth is insufficient.

FIG. 3 is a schematic diagram of an embodiment of the bandwidth modification unit according to the invention.

FIG. 4 is a schematic diagram of part of a digitally controlled oscillator 500.

FIG. 5 is a flowchart of an embodiment of a method for adjusting the bandwidth of an all-digital phase-locked loop according to the invention.

FIG. 6 is a schematic diagram of an embodiment of a loop filter 600 according to the invention.

FIG. 7 is a schematic of an embodiment of decision circuit 700 according to the invention.

FIG. 8 is a schematic diagram of another embodiment of a loop filter 800 according to the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

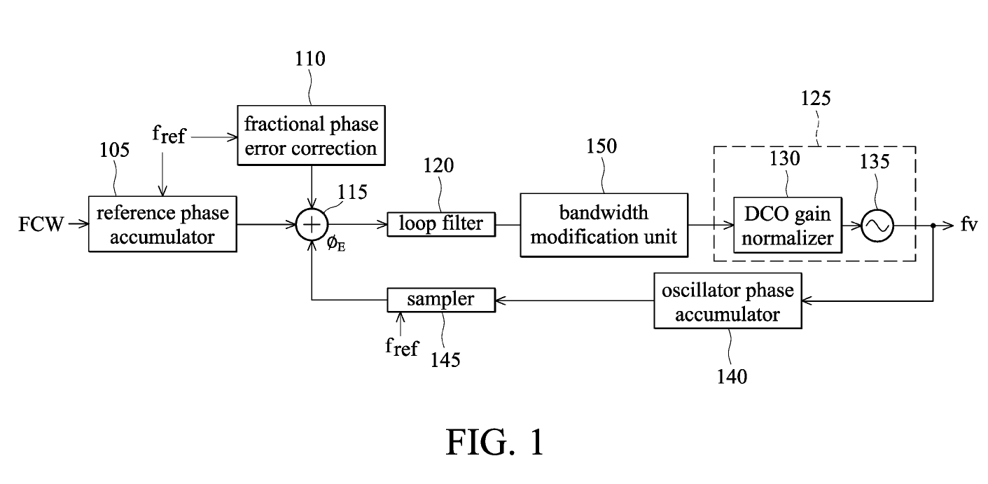

FIG. 1 is a schematic diagram of an embodiment of an all-digital phase-locked loop according to the invention. The phase error ψ_{E} between the variable signal fᵥ and reference signal f_{ref} can be determined by the phase detector 115. As shown in FIG. 1, the phase detector 115 has three inputs, where one input is provided by inputting the reference signal f_{ref} to the reference phase accumulator 105 and is regarded as the phase of the reference signal f_{ref}. Another input is provided by inputting the variable signal fᵥ to the oscillator phase accumulator 140 and the sampler 145 and is regarded as the phase of the reference signal fᵥ. The last input is the fractional phase error between the variable signal fᵥ and reference signal f_{ref}. The sum of the three inputs is the phase error ψ_{E}.

At beginning, the phase-locked loop locks the phase quickly. The loop filter 120 filters the phase error ψ_{E} and/or adjusts the magnitude of phase error ψ_{E}. The loop filter 120 generates an oscillator tuning word (OTW) to modify the output of a digitally controlled oscillator (DCO) 125, i.e. the variable signal fᵥ. The digitally controlled oscillator 125 comprises a plurality of capacitor sets and the capacitance of the capacitor banks is controlled by an oscillator tuning word, and variable signal fᵥ is generated according to the capacitance and inductance of an inductor coupled to the capacitor banks. The oscillator tuning word respectively controls the capacitance of corresponding capacitor bank. Typically, the oscillator tuning word comprises a process-voltage-temperature (PVT) tuning word, an acquisition (ACQ) tuning word, and a tracking (ACK) tuning word which respectively controls the capacitance of the PVT capacitor bank, ACQ capacitor bank and track capacitor bank.

For example, the oscillator tuning word output by the loop filter 120 has 24 bits, OTW[0:23], wherein the 8 bits OTW[16:23] is the PVT tuning word, the 8 bits OTW[8:15] is the ACQ tuning word, and the 8 bits OTW[0:7] is the ACK tuning word. The frequency range of the digitally controlled oscillator capable to be adjusted by the PVT tuning word is large and thus accordingly, the adjustment step is also large. The PVT tuning word generally reduces the bad effect due to the process, voltage and the temperature of the chip. The frequency range of the digitally controlled oscillator capable to be adjusted by the ACK tuning word is small and thus accordingly, the accuracy of adjustment is large. The ACK tuning word is used for calibrating the frequency of the all-digital phase-locked loop when tracking the carrier signal. The frequency range of the digitally controlled oscillator capable to be adjusted by the ACQ tuning word and corresponding accuracy of adjustment is within the average. The ACQ tuning word is used for calibrating the frequency of the all-digital phase-locked loop when determining the frequency channel.

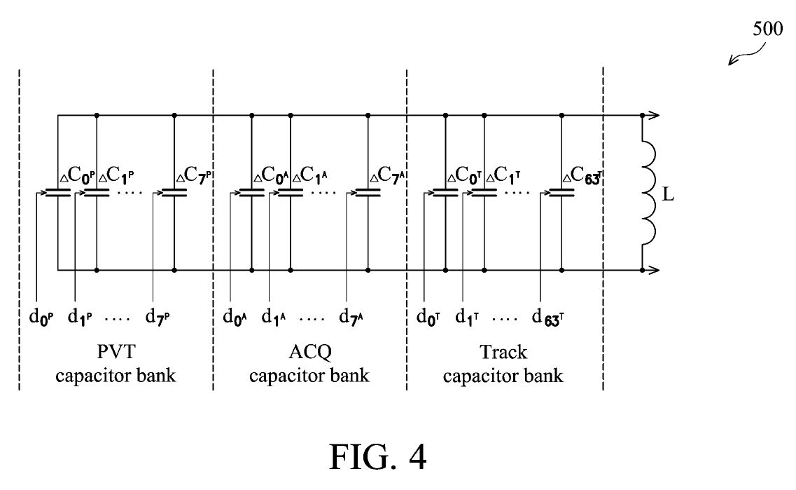

FIG. 4 is a schematic diagram of part of a digitally controlled oscillator 500. The digitally controlled oscillator 500 comprises one inductor and a plurality of capacitors, and its output frequency is determined by the following equation: f_{DCO}=1/squr(L*Cₜₒₜₐₗ), wherein the Cₜₒₜₐₗ is the sum of the capacitances of activated capacitors. The capacitors in the digitally controlled oscillator 500 are substantially divided into three banks: a PVT capacitor bank, an ACQ capacitor bank, and a tracking bank. The capacitors in the PVT capacitor bank are ΔC₀^{P} . . . ΔC₇^{P}, arranged binary-weighted, respectively selected by the control signals d₀^{P} . . . d₇^{P}. The PVT tuning word is applied to some interfaces and the control signal is generated after the PVT tuning word is processed by the interfaces. In other word, the capacitors in the PVT capacitor bank are controlled by the PVT tuning word.

Similarly, the capacitors in the ACQ capacitor bank are controlled by the ACQ tuning word. The capacitors ΔC₀^{T} . . . ΔC₆₃^{T} in the tracking band are the same (unit-weighted) and the capacitance of each capacitor is designed as small as possible. The signals d₀^{T} . . . d₆₃^{T} are generated after the tracking tuning word is decoded and processed by some interface. As previously described, the PVT tuning word coarsely adjusts the output frequency of the digitally controlled oscillator. The tracking tuning word finely adjusts the output frequency of the digitally controlled oscillator and the ACQ tuning word averagely adjusts the output frequency of the digitally controlled oscillator. Therefore, the smallest capacitor in the PVT capacitor bank is larger than the smallest capacitor in the ACQ capacitor bank and the smallest capacitor in the ACQ capacitor bank is larger than each capacitor in the tracking bank and the partial tracking bank.

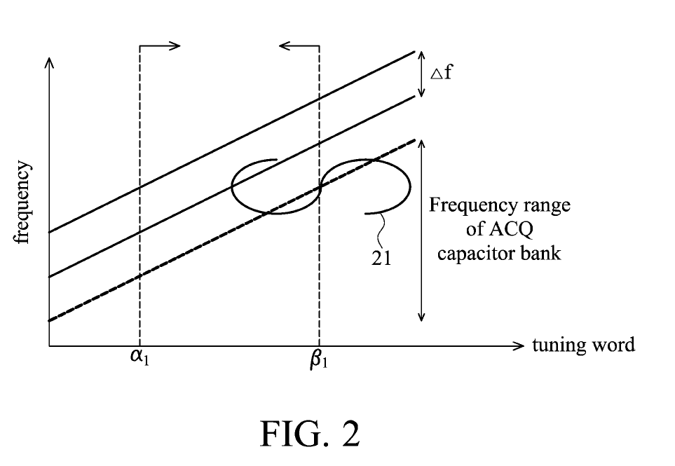

Before the all-digital phase-locked loop locks the phase, the bandwidth modification unit 150 first enables all the capacitors in all capacitor banks. In other words, the capacitors in the capacitor banks can be determined to be used or not according to control signals, such as the control signals d₀^{P} . . . d₇^{P}. When the all-digital phase-locked loop locks the phase, the corresponding capacitance maybe set at the capacitance margin of the capacitor banks, and this may cause the capacitance required by the phase modulation is insufficient, such as shown in FIG. 2.

In FIG. 2, curve 21 indicates the frequency variation when phase modulation. According to FIG. 2, though the all-digital phase-locked loop has been phase locked, the frequency margin of the ACQ capacitor bank is not sufficient and this easily causes the phase modulation error. Furthermore, the PVT capacitor bank does not change or to be calibrated during phase modulation. Therefore, if designer wants larger bandwidth for phase modulation, the usage range of the ACQ capacitor bank has to be adjusted, and the all-digital phase-locked loop has to lock phase again to ensure that the capacitor bank can provide more available capacitors. In FIG. 2, α₁ and β₁ indicate the upper value and the bottom value of the usage range of the ACQ capacitor bank.

When the all-digital phase-locked loop first locks phase, α₁ is 0 and β₁ is the maximum value, i.e., the all capacitors in the ACQ capacitor bank are set to be used. After the all-digital phase-locked loop first locks phase, the capacitance of the ACQ capacitor bank is limited to the capacitance corresponding between α₁ and β₁, and the bandwidth modification unit determines whether the margin capacitance of the ACQ capacitor bank is larger than a predetermined value, such as BW_{ACQ}/3, wherein BW_{ACQ} is the bandwidth provided by the ACQ capacitor bank. If the margin capacitance of the ACQ capacitor bank is larger than a predetermined value, the all-digital phase-locked loop does not have to be calibrated again, the all capacitors in the ACQ capacitor bank are set to be available for signal modulation. If the margin capacitance of the ACQ capacitor bank is not larger than a predetermined value, the all-digital phase-locked loop is calibrated again, and the capacitance of the ACQ capacitor bank is limited to the capacitance corresponding between α₁ and β₁. After calibrating, the bandwidth modification unit determines whether the margin capacitance of the ACQ capacitor bank is larger than a predetermined value again, and if not, the α₁ value increase and β₁ value decreases, and the all-digital phase-locked loop is calibrated again until the margin capacitance of the ACQ capacitor bank is larger than a predetermined value.

In one embodiment, the increased value of α₁ and the decreased value of β₁ are the same, but not limit the invention thereto, i.e., the increased value of α₁ and the decreased value of β₁ can be different. Similarly, the calibration mechanism of the track capacitor bank is similar to the calibration mechanism of the ACQ capacitor bank.

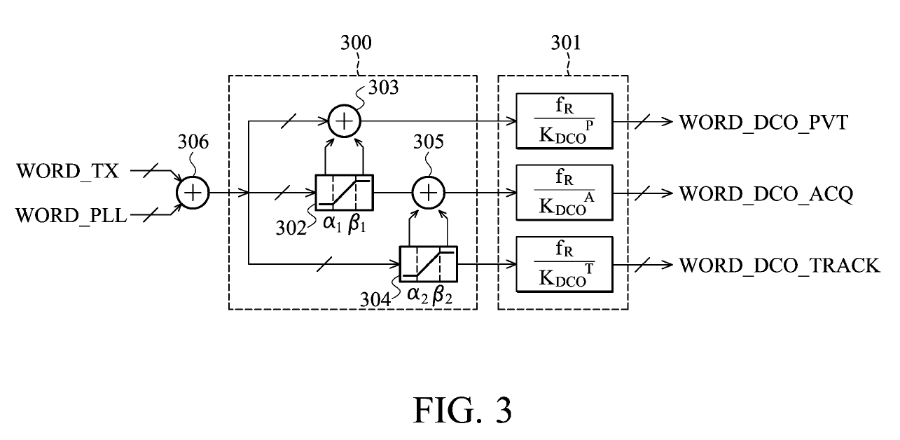

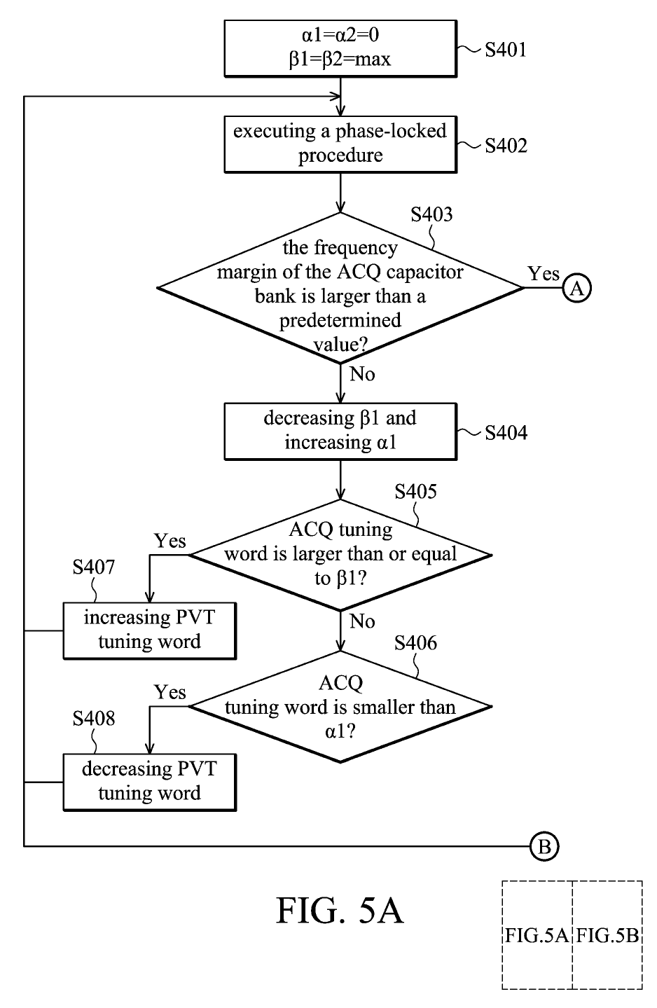

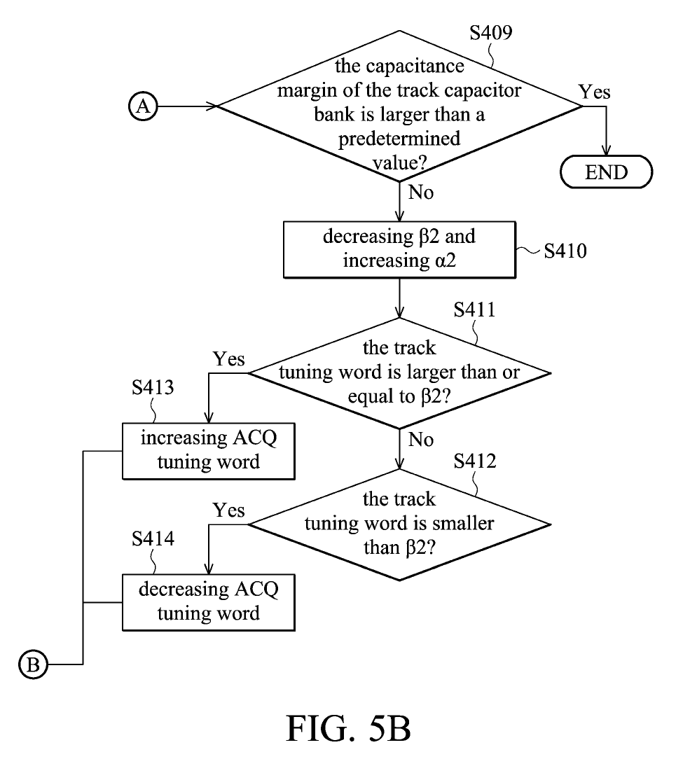

FIG. 3 is a schematic diagram of an embodiment of the bandwidth modification unit according to the invention. The adder 306 receives the oscillator tuning word from the loop filter 120. The oscillator tuning word WORD_PLL from the loop filter 120 indicates the initial oscillator tuning word, the PVT tuning word WORD_DCO_PVT, ACQ tuning word WORD_DCO_ACQ and the track tuning word WORD_DCO_TRACK are the tuning words after calibrating and input to the digitally controlled oscillator 125. When the all-digital phase-locked loop locks phase, the adder 306 only receives the oscillator tuning word WORD_PLL. When the all-digital phase-locked loop becomes a transmitter, the 8 bits [16:23] of the oscillator tuning word WORD_PLL is the PVT tuning word and transmitted to the adder 303, the 8 bits [8:15] of the oscillator tuning word WORD_PLL is the ACQ tuning word and transmitted to the control unit 302, and the 8 bits [0:7] of the oscillator tuning word WORD_PLL is the ACK tuning word and transmitted to the control unit 304. The operation of the control units 302 and 304 can be referred to the flowchart in FIG. 5.

FIG. 5 is a flowchart of an embodiment of a method for adjusting the bandwidth of an all-digital phase-locked loop according to the invention. In step S401, the control units 302 and 304 enable all the capacitors in ACQ capacitor bank and track capacitor bank, and then, the phase-locked loop executes a phase-locked procedure in step S402. When the phase-locked loop finishes the phase-locked procedure, the decision unit 302 sets a first upper value β₁ and a first bottom value α₁, receives the ACQ tuning word and determines whether the frequency margin of the ACQ capacitor bank is larger than a predetermined value (step S403). If the frequency margin of the ACQ capacitor bank is not larger than a predetermined value, the procedure goes to step S404, and the decision unit 302 decreases the first upper value β₁ and increases the first bottom value α₁. At the same time, the decision unit 302 determines whether the ACQ tuning word is larger than or equal to β₁ (Step S405). If yes, the PVT tuning word increases (Step S407) and the procedure returns back to the step S402 to re-execute the phase-locked procedure. In this embodiment, the PVT tuning word increases by 1 in each time, but not limit the invention thereto. If the ACQ tuning word is not larger than or equal to β₁, the decision unit 302 determines whether the ACQ tuning word is less than or equal to α₁. If yes, the PVT tuning decreases (Step S408) and the procedure returns back to the step S402 to re-execute the phase-locked procedure. In this embodiment, the PVT tuning word decreases by 1 in each time, but not limit the invention thereto.

In step S409, the bandwidth modification unit 300 determines whether the capacitance margin of the track capacitor bank is larger than a predetermined value. If yes, this indicates that the capacitors in the track capacitor bank and ACQ capacitor bank is sufficient for the phase modulation and the bandwidth calibration procedure is finished. If the capacitance margin of the track capacitor bank is smaller than a predetermined value, the decision unit 304 decreases the first upper value β₂ and increases the first bottom value α₂ (Step S410). At the same time, the decision unit 304 determines whether the track tuning word is larger than or equal to β₂ (S411). If yes, the ACQ tuning word increases and the procedure returns back to the step S402 to re-execute the phase-locked procedure. In this embodiment, the ACQ tuning word increases by 1 in each time, but not limit the invention thereto. If the ACQ tuning word is less than β₂, the procedure goes to step S412 and the decision unit 304 determines whether the track tuning word is less than or equal to α₂. If yes, the ACQ tuning decreases and the procedure returns back to the step S402 to re-execute the phase-locked procedure. In this embodiment, the ACQ tuning word decreases by 1 in each time, but not limit the invention thereto.

According to the described mechanism to apply a phase-locked calibration on the all-digital phase-locked loop, the digital phase-locked loop can quickly phase lock and ensure enough bandwidth for signal modulation. According to the described calibration mechanism, the usage bandwidth for signal modulation can be increase without modifying the architecture of capacitor banks. Furthermore, the bandwidth for signal modulation can be adjusted by external firmware or Field Programmable Gate Array, FPGA.

In the following, a loop filter of the present application is provided. The provided loop filter can quickly phase lock and has lower phase noise.

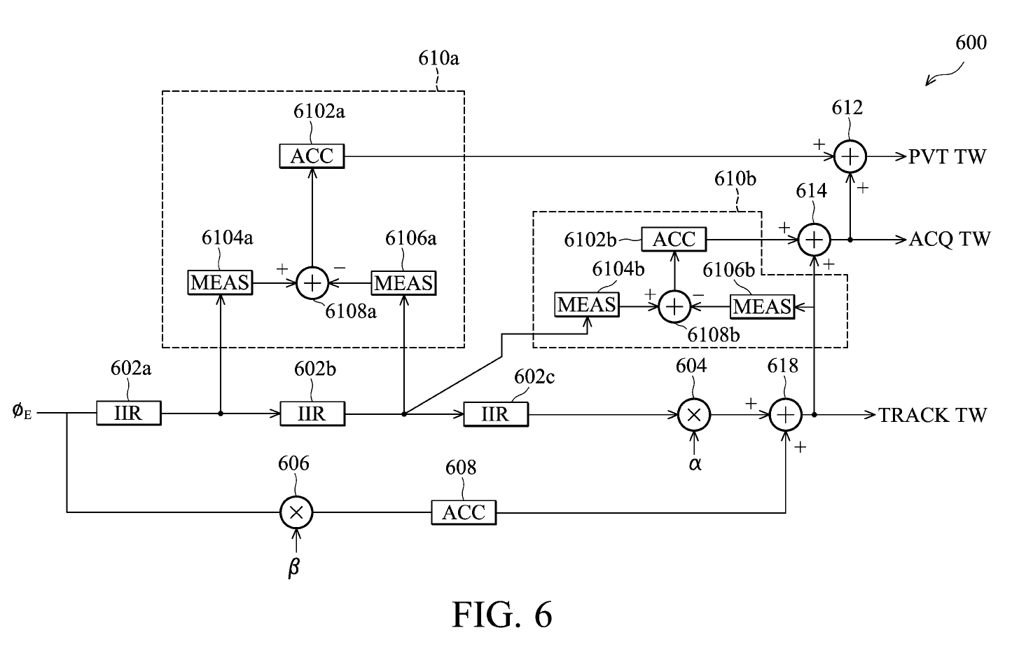

FIG. 6 is a schematic diagram of an embodiment of a loop filter 600 according to the invention. The loop filter 600 receives the phase error ψ_{E} and accordingly controls a digitally controlled oscillator. The loop filter 600 of FIG. 6 has a plurality of stages of the low pass filters 602a-602c. In FIG. 6, each low pass filter is an infinite-impulse-response (IIR) filter or a finite-impulse-response (FIR) filter. The output of the low pass filter 602c can be transmitted to a multiplier 604 to be multiplied with a loop gain α. The loop gain α also can be applied to other low pass filters to adjust the filter output of each low pass filter. The phase error ψ_{E} can be multiplied with a loop gain β, by a multiplier 606, and then transmitted to the accumulator 608. The sum of the multiplier 604 and accumulator 608 generates the tracking tuning word. In a word, the low pass filters 602a to 602c and the multiplier 604 forms a type II higher order filter and its time response is slower because the phase error ψE is processed by several stages of the low pass filters and accordingly the tracking tuning word is affected by the phase error ψ_{E}. The multiplier 606 and accumulator 608 provide a faster path for the phase error ψ_{E} to affect the tracking tuning word.

The loop filter 600 of FIG. 6 further comprises two modification circuits 610a and 610b. The modification circuit 610a has two decision circuits, 6104a and 6106a, an accumulator 6102a and an adder 6108a. The modification circuit 610b has two decision circuits, 6104b and 6106b, an accumulator 6102b and an adder 6108b. Although the function block diagrams of the modification circuits 610a and 610b shown in FIG. 6 are the same as each other, the circuits of the same function block may be implemented by different circuits.

The modification circuit 610a directly detects the outputs of the low pass filters 602a and 602b. Once the modification circuit 610a detects that the outputs of the low pass filters 602a and 602b meet a predetermined condition, the modification circuit 610a modifies the PVT tuning word via the adder 612. Thus, the frequency of the all-digital phase-locked loop, i.e. the frequency of the variable signal fᵥ, can be significantly changed.

The modification circuit 610b directly detects the output of the low pass filter 602b and indirectly detects the output of the last stage of the low pass filter, i.e. the low pass filter 602c, via the multiplier 604 and adder 618. Once the modification circuit 610b detects that the outputs of the low pass filters 602b and 602c meet a predetermined condition, the modification circuit 610b modifies the ACQ tuning word, wherein the predetermined condition of the modification circuit 610a may be the same as or different from the predetermined condition of the modification circuit 610b.

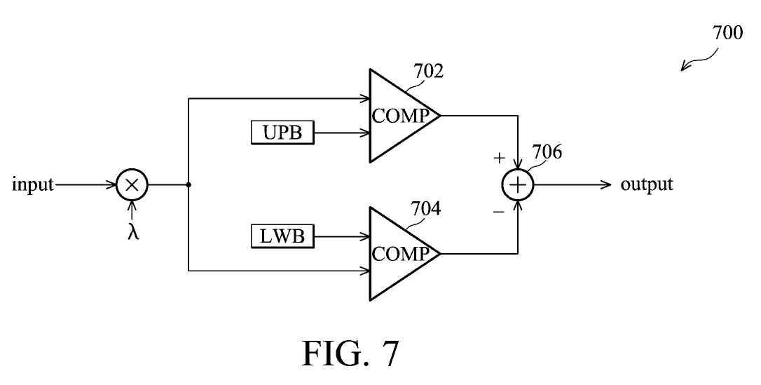

FIG. 7 is a schematic diagram of an embodiment of a decision circuit 700 according to the invention. The decision circuit shown in FIG. 7 can be applied to the decision circuit 6104a, 6104b, 6106a or 6106b. The comparator 702 compares the input of the decision circuit 700 and a predetermined upper bond (UPB), and the comparator 704 compares the input of the decision circuit 700 and a predetermined lower bond (LWB). The output of the comparator 702 or comparator 704 is 1 or −1, and the sum of the two outputs, by the adder 706, is the output of the decision circuit 700. The function of the decision circuit 700 is described in the following. If the input of the decision circuit 700 is higher than the UPB, the output of the decision circuit 700 is 1. If the input of the decision circuit 700 is lower than the LWB, the output of the decision circuit 700 is −1. If the input of the decision circuit 700 is between the LWB and UPB, the output of the decision circuit 700 is 0. If the output of the decision circuit 700 varies acutely, the input of the decision circuit 700 can be multiplied with a parameter λ to decrease the variation of the output of the decision circuit 700.

Take the modification circuit 610b in FIG. 6 for example, if the decision circuits 6104b and 6106b adopt the decision circuit 700 in FIG. 7, the UPB and LWB of the decision circuit 6104b respectively is UPBa and LWBa, and the UPB and LWB of the decision circuit 6106b respectively is UPBb and LWBb, the function of the modification circuit 610b is described in the following.

When the phase is approximately locked, i.e., the phase error ψ_{E} is very small, the output of the filter 602b is substantially maintained between UPBa and LWBa, and the output of the filter 602c is substantially maintained between UPBb and LWBb. Accordingly, the outputs of the decision circuits 6104b and 6106b are 0, and the output of the accumulator 6102b does not change. Thus, the ACQ tuning word is not affected by the output of the accumulator 6102b.

When the phase error ψ_{E} increases, the output of the filter 602b may diverge from the range between UPBa and LWBa, and the output of the filter 602c may later diverge from the range between UPBb and LWBb. The time delay is because the output of the low pass filter 602c is generated by low pass filtering the output of the low pass filter 602b. For example, when the output of the low pass filter 602b suddenly exceeds UPBa and the output of the low pass filter 602c is still between the UPBb and LWBb, the output of the decision circuit 6104b becomes 1, the output of the decision circuit 6106b is still 0, and the output of the accumulator 6102b periodically increases by 1 according to the input clock signal. Thus, the modification circuit 610b periodically increases the ACQ tuning word by 1. The output of the low pass filter 602c follows the output of the low pass filter 602b, but the output of the low pass filter 602c later varies. Once the output of the low pass filter 602c is larger than UPBb, the outputs of the decision circuits 6104b and 6106b are also 1, the accumulator 6102b stops increasing its output and the modification circuit 610b also stops increasing the ACQ tuning word. Similarly, when the outputs of the low pass filters 602b and 602c decrease, the modification circuit 610b may periodically decrease the ACQ tuning word and after a period of time, the modification circuit 610b stops affecting the ACQ tuning word.

In other words, the modification circuit 610b determines whether the amount of times the low pass filter 602b is output is too much according to the UPBa and LWBa. Once the amount of times the low pass filter 602b is output is too much, the modification circuit 610b roughly adjusts the output frequency of a digitally controlled oscillator. The UPBb and LWBb serve as a stop mechanism for the modification circuit 610b. In other words, the UPBb and LWBb determine the amount of frequency adjustments.

According to the above description of the modification circuit 610b, those skilled in the art can easily understand the operation of the modification circuit 610a. When the modification circuit 610a determines that the amount of times the low pass filter 602a is output is too much, the modification circuit 610a coarsely adjusts the output frequency of a digitally controlled oscillator. Through the output of the low pass filter 602b, the modification circuit 610a stops adjusting the output frequency of the digital controlled oscillator, and the frequency adjustment amount is also determined.

As to the UPB and LWB of each decision circuit, the UPB and LWB are respectively determined based on circuit design or requirement.

The modification circuits 610a and 610b quickly and coarsely adjust the output frequency of a digitally controlled oscillator. Without the modification circuits 610a and 610b in FIG. 6, the PVT tuning word can only be affected by the carry bit of the ACQ tuning word, and the ACQ tuning word only can be affected by the carry bit of the ACK tuning word. Thus, the PVT tuning word and the ACQ tuning word can only be increased or decreased by 1 after each phase-locked operation. Compared with the described modification circuit, the modification circuits 610a and 610b in FIG. 6 provide a mechanism for quickly and coarsely adjusting the output frequency of the digitally controlled oscillator by a large margin. It can be expected that an all-digital phase-locked loop with the loop filter 600 in FIG. 6 can lock its phase quickly.

Although the loop filter 600 in FIG. 6 is shown by a functional block, the loop filter 600 can be implemented by hardware or software.

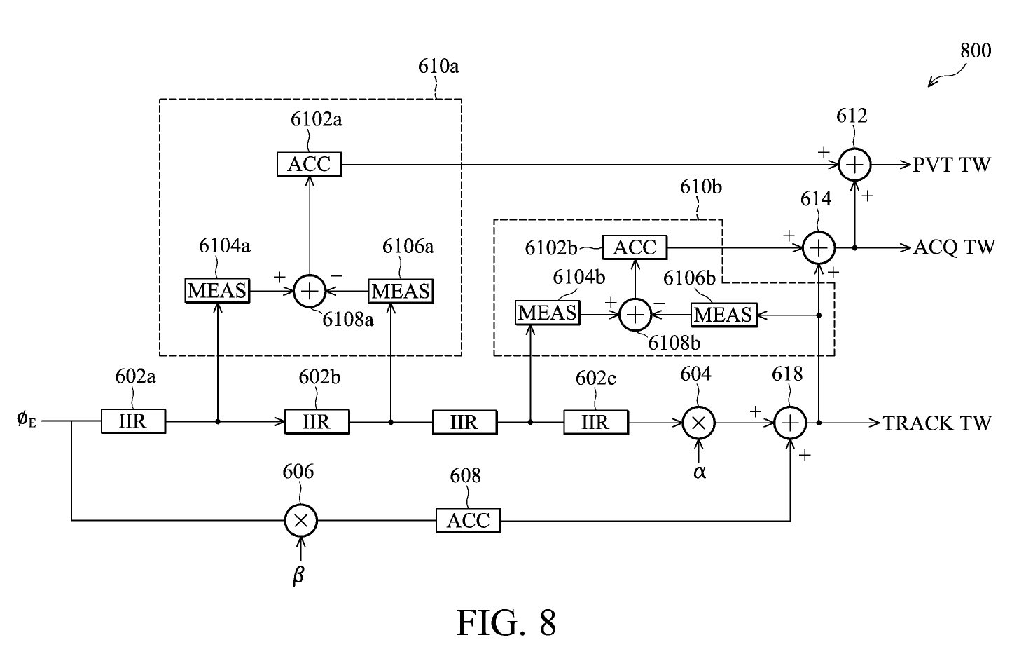

Please refer to FIG. 6, wherein the modification circuit 610a is coupled to the low pass filter 602a and the low pass filter 602b, the low pass filter 602a is a front low pass filter, and the low pass filter 602b is a back low pass filter to process the filter output of the low pass filter 602a. Similarly, the modification circuit 610b is coupled to the low pass filter 602b and the low pass filter 602c, the low pass filter 602b is a front low pass filter, and the low pass filter 602c is a back low pass filter. Thus, the low pass filter 602b is the back low pass filter detected by the modification circuit 610a and the front low pass filter detected by the modification circuit 610b. However, it is not necessary that the modification circuits 610a and 610b detect the same low pass filter. FIG. 8 is a schematic diagram of another embodiment of a loop filter 800 according to the invention, wherein the modification circuits 610a and 610b do not detect the same low pass filter.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for adjusting the bandwidth of an all-digital phase-locked loop, wherein the all-digital phase-locked loop comprises a digitally controlled oscillator controlled by an oscillator tuning word to generate a variable signal, the oscillator tuning word comprises a first tuning word and a second tuning word respectively to adjust the capacitance of a first capacitor set and the capacitance of a second capacitor set, and the frequency range of the digitally controlled oscillator capable to be adjusted by the first tuning word is broader than that capable to be adjusted by the second tuning word, the method comprising:
enabling both the first capacitor set and the second capacitor set;
executing a frequency-phase-locked processing by the all-digital phase-locked loop;
setting the capacitance variation range of the second capacitor set to be between a first upper value and a first bottom value;
determining whether the second tuning word is between the first upper value and the first bottom value; and
when the second tuning word is not between the first upper value and the first bottom value, adjusting the first tuning word and the all-digital phase-locked loop re-executing the frequency-phase-locked procedure.

2. The method as claimed in claim 1, when the second tuning word is between the first upper value and the first bottom value, setting the second capacitor set to be available.

3. The method as claimed in claim 1, further comprising:
when the available usage range of the second capacitor set is smaller than a predetermined value, reducing the first upper value for a first predetermined value; and
increasing the first bottom value for a second predetermined value.

4. The method as claimed in claim 1, wherein the tuning word further comprises a third tuning word to adjust the capacitance of a third capacitor set and, the method further comprises:
setting the capacitance variation range of the third capacitor set to be between a second upper value and a second bottom value;
determining whether the third tuning word is between the second upper value and the second bottom value; and
when the third tuning word is not between the second upper value and the second bottom value, adjusting the second tuning word and the all-digital phase-locked loop re-executing the frequency-phase-locked procedure.

5. The method as claimed in claim 4, when the third tuning word is between the second upper value and the second bottom value, setting the third capacitor set to be available.

6. The method as claimed in claim 4, further comprising:
when the available usage range of the third capacitor set is smaller than a predetermined value, reducing the second upper value for a first predetermined value; and
increasing the second bottom value for a second predetermined value.

7. The method as claimed in claim 1, wherein
the second capacitor set comprises a plurality of second capacitors with the same capacitance, controlled by the second tuning word; and
the first capacitor set comprises a plurality of first capacitors, controlled by the first tuning word, wherein the capacitance of each the first capacitor is larger than each one of the second capacitor.

8. An all-digital phase-locked loop, comprising:
a digitally controlled oscillator, controlled by an oscillator tuning word to generate a variable signal, the oscillator tuning word comprises a first tuning word and a second tuning word respectively to adjust the capacitance of a first capacitor set and the capacitance of a second capacitor set, and the frequency range of the digitally controlled oscillator capable to be adjusted by the first tuning word is broader than that capable to be adjusted by the second tuning word;
a phase detector to measure a phase error between the variable signal and a reference signal;
a loop filter to receive the phase error to generate an initial tuning word; and
a bandwidth modification unit to receive the initial tuning word to adjust the initial tuning word to generate the tuning word according to the available usage range of the first capacitor set and the second capacitor set.

9. The all-digital phase-locked loop as claimed in claim 8, when the all-digital phase-locked loop executes a phase-locked procedure, the second capacitor set are set to be all available, and when the all-digital phase-locked loop completes the phase-locked procedure, the capacitance variable range of the second capacitor set is between a first upper value and a first bottom value.

10. The all-digital phase-locked loop as claimed in claim 9, after the all-digital phase-locked loop completes the phase-locked procedure, the bandwidth modification unit determines whether the second tuning word is at the range between the first upper value and the first bottom value, and when the second tuning word is not between the first upper value and the first bottom value, the first tuning word is adjusted and the all-digital phase-locked loop re-executes the frequency-phase-locked procedure.

11. The all-digital phase-locked loop as claimed in claim 10, wherein when the second tuning word is between the first upper value and the first bottom value, setting the second capacitor set to be completely available.

12. The all-digital phase-locked loop as claimed in claim 8, wherein when the bandwidth modification unit determines that the available usage range of the second capacitor set is smaller than a predetermined value, the bandwidth modification unit reduces the first upper value for a first predetermined value and increases the first bottom value for a second predetermined value.

13. The all-digital phase-locked loop as claimed in claim 8, wherein the oscillator further comprises a third capacitor set controlled by a third tuning word, and the frequency range of the digitally controlled oscillator capable to be adjusted by the second tuning word is broader than that capable to be adjusted by the third tuning word.

14. The all-digital phase-locked loop as claimed in claim 13, wherein when the all-digital phase-locked loop executes a phase-locked procedure, the third capacitor set is enabled, and when the all-digital phase-locked loop completes the phase-locked procedure, the capacitance variable range of the third capacitor set is between a second upper value and a second bottom value.

15. The all-digital phase-locked loop as claimed in claim 14, wherein after the all-digital phase-locked loop completes the phase-locked procedure, the bandwidth modification unit determines whether the third tuning word is at the range between the second upper value and the second bottom value, and when the third tuning word is not between the second upper value and the second bottom value, the second tuning word is adjusted and the all-digital phase-locked loop re-executes the frequency-phase-locked procedure.

16. The all-digital phase-locked loop as claimed in claim 15, wherein when the third tuning word is between the second upper value and the second bottom value, setting the third capacitor set to be completely available.

17. The all-digital phase-locked loop as claimed in claim 13, wherein when the bandwidth modification unit determines that the available usage range of the third capacitor set is smaller than a predetermined value, the bandwidth modification unit reduces the second upper value for a first predetermined value and increases the second bottom value for a second predetermined value.

18. The all-digital phase-locked loop as claimed in claim 8, wherein
the second capacitor set comprises a plurality of second capacitors with the same capacitance and is controlled by the second tuning word; and
the first capacitor set comprises a plurality of first capacitors and is controlled by the first tuning word, wherein the capacitance of each the first capacitor is larger than each one of the second capacitor.

19. The all-digital phase-locked loop as claimed in claim 8, wherein the loop filter comprises:
a plurality of stages of low pass filters; and
a modification circuit to detect two filter outputs from two low pass filters among those filters and accordingly adjust the second tuning word.

20. The all-digital phase-locked loop as claimed in claim 19, wherein the detected two low pass filters are a front filter and a back filter, and the modification circuit comprise:
a first decision circuit to detect the filter output of the back filter and accordingly output a first variation;
a second decision circuit to detect the filter output of the front filter and accordingly output a second variation; and
an accumulator to accumulate the difference between first variation and the second variation and accordingly adjust the second tuning word.
